(19) United States
(12) Patent Application Publication
(10) Pub. No.: US 2002/0124792 A1
(43) Pub. Date: Sep. 12, 2002

(54) Crystal puller and method for growing single crystal semiconductor material

(76) Inventors: Hariprasad Sreedharamurthy, Ballwin, MO (US); Mohsen Banan, Grover, MO (US); John Holder, Lake St. Louis, MO (US); Lee Ferry, St. Charles, MO (US)

Correspondence Address: SENNIGER POWERS LEAVITT AND ROEDEL, ONE METROPOLITAN SQUARE, 16TH FLOOR, ST LOUIS, MO, 63102, US

(21) Appl. No.: 09/757,121

(22) Filed: Jan. 9, 2001

(51) Int. Cl. C30B 15/00; C30B 21/06; C30B 27/02; C30B 28/10; C30B 30/04; C30B 35/00

(52) U.S. Cl. 117/13; 117/208

(57) ABSTRACT

A crystal puller and method for growing single crystal semiconductor material having a susceptor assembly that includes a susceptor disposed in the crystal puller for receiving and holding a crucible. The side wall of the susceptor is in generally radially opposed relationship with the side wall of the crucible. A sealing member of the assembly is adapted for close contact relationship with the crucible side wall and the susceptor side wall to generally seal between the crucible and the susceptor any gaseous product resulting from a reaction of the crucible with the susceptor against escape from between the crucible and the susceptor, thereby inhibiting the reaction of the crucible with the susceptor.

### BACKGROUND OF THE INVENTION

The present invention relates to a crystal puller for growing single crystal semiconductor material, and more particularly to such a crystal puller having a susceptor assembly for increasing the useful life of a susceptor disposed in the crystal puller.

Single crystal semiconductor material, which is the starting material for fabricating many electronic components, is commonly prepared using the Czochralski (“Cz”) method. In this method, polycrystalline semiconductor source material such as polycrystalline silicon (“polysilicon”) is melted in a crucible. The crucible is seated in a susceptor mounted on a turntable for rotation of the susceptor and crucible about a central axis of the crystal puller as the monocrystalline silicon ingot is being grown. The crucible is also capable of being raised within the growth chamber to maintain the surface of the molten source material at a generally constant level as the ingot is grown and source material is removed from the melt.

After the source material is melted in the crucible, a seed crystal is lowered into the molten material and slowly raised to grow a single crystal ingot. As the ingot is grown, an upper end cone is formed by decreasing the pull rate and/or the melt temperature, thereby enlarging the ingot diameter, until a target diameter is reached. Once the target diameter is reached, the cylindrical main body of the ingot is formed by controlling the pull rate and the melt temperature to compensate for the decreasing melt level. Near the end of the growth process but before the crucible becomes empty, the ingot diameter is reduced to form a lower end cone which is separated from the melt to produce a finished ingot of semiconductor material.

In conventional crystal pullers, the crucible is a unitary piece constructed of quartz (i.e., fused silica) and the susceptor, which is of two or more pieces to allow for expansion and contraction of the quartz crucible held in the susceptor, is made of graphite. As a result of the multiple piece construction of the susceptor, there is often a small gap along the seam, or seams, where the susceptor pieces come together. Also, due to manufacturing specifications and tolerances associated with the manufacture of crucibles and susceptors, the crucible may not always seat within the susceptor in close contact with the entire inner surface of the susceptor. As a result, there may also be one or more gaps between the outer surface of the crucible side wall and the inner surface of the susceptor side wall, including at the annular seam between the top of the susceptor and the crucible.

At high operating temperatures in the crystal puller, such as 1500° C., graphite reacts with quartz (i.e., fused silica) as follows:

SiO2+C→SiO+CO [1]

SiO+2C→SiC+CO [2]

The first reaction [1] is a solid state reaction resulting in gaseous SiO as a product, which then reacts with the graphite in accordance with the second reaction [2] to form SiC. The SiC is formed by conversion of graphite and therefore introduces stresses inside the susceptor. The stresses developed in the susceptor may result in distortion of the susceptor or otherwise render the susceptor prone to cracking or failing. The conversion of graphite also tends to substantially widen the gaps in the seams between the susceptor pieces and between the crucible side wall and the susceptor side wall. Thus, the formation of SiC in accordance with the chemical reaction occurring between the quartz crucible, the graphite susceptor and the SiO gas negatively effects the useful lifetime of the susceptor.

To this end, Japanese Patent No. JP6293588 discloses inserting a heat-resistant sheet, such as a sheet constructed of carbon fiber composite, between the crucible and the graphite susceptor to blanket the graphite susceptor over substantially the entire inner surface of the susceptor. The heat-resistant sheet generally shields the graphite susceptor from the quartz crucible so that conversion of the graphite susceptor is inhibited. As a result, the useful lifetime of the graphite susceptor is increased. However, because of the rigidity of the heat-resistant sheet and the manufacturing tolerances associated with manufacturing the quartz crucible, the graphite susceptor and the heat-resistant sheet, gaps are still present between the crucible and the heat-resistant sheet. Therefore, the quartz crucible reacts with the heat-resistant sheet instead of the susceptor, resulting in conversion of the heat-resistant sheet. Consequently, the heat-resistant sheet requires frequent replacement.

### SUMMARY OF THE INVENTION

Among the several objects and features of the present invention may be noted the provision of a crystal puller having a susceptor assembly therein which inhibits the chemical reaction between a quartz crucible and a graphite susceptor holding the crucible in the crystal puller; the provision of such a crystal puller having such a susceptor assembly that inhibits conversion of the graphite susceptor to SiC; the provision of such a crystal puller having such a susceptor assembly which increases the useful lifetime of the susceptor; the provision of such a susceptor assembly which is easy to install in the crystal puller; and the provision of such a susceptor assembly which is less costly to manufacture and to use.

In general, a crystal puller of the present invention for producing a monocrystalline ingot comprises a susceptor having a bottom and a side wall. A crucible for holding molten source material is received in the susceptor and has a side wall disposed in generally radially opposed relationship with the susceptor side wall. A heater is in thermal communication with the susceptor and crucible for heating the crucible to a temperature sufficient to melt the semiconductor source material held by the crucible. A pulling mechanism is positioned above the crucible for pulling the ingot from the molten material held by the crucible. A sealing member is adapted for close contact relationship with the crucible side wall and the susceptor side wall to generally seal between the crucible and the susceptor any gaseous product resulting from a reaction of the crucible with the susceptor against escape from between the crucible and the susceptor, thereby retarding the reaction of the crucible with the susceptor.

A susceptor assembly of the present invention for use in a crystal puller of the type described above comprises a susceptor having a bottom and a side wall. The susceptor is sized for receiving and holding the crucible in the crystal puller. The side wall of the susceptor is in generally radially opposed relationship with a side wall of the crucible. The assembly also comprises a sealing member adapted for close contact relationship with the crucible side wall and the susceptor side wall to generally seal between the crucible and the susceptor any gaseous product resulting from a reaction of the crucible with the susceptor against escape from between the crucible and the susceptor, thereby retarding the reaction of the crucible with the susceptor.

A method of the present invention for growing monocrystalline ingots generally comprises seating a crucible in a susceptor mounted in a crystal puller. The susceptor has a bottom and a side wall in generally radially opposed relationship with a side wall of the crucible. Source material is charged to the crucible and the susceptor and crucible are heated to a temperature sufficient to melt the semiconductor source material held by the crucible. This heating causes the crucible to react with the susceptor generally therebetween to produce a gaseous product. The gaseous product is generally sealed between the susceptor and crucible to increase the concentration of the gaseous product therebetween, thereby inhibiting further reaction of the crucible with the susceptor.

Other objects and features of the present invention will be in part apparent and in part pointed out hereinafter.

### BRIEF DESCRIPTION OF THE DRAWINGS

FIG. 1 is a fragmentary vertical cross-section of a crystal puller of the present invention including a susceptor assembly;

FIG. 2 is a fragmentary vertical cross-section of a crucible received in the susceptor assembly of the crystal puller of FIG. 1;

FIG. 3 is a top plan view of the crucible and susceptor assembly of FIG. 2;

FIG. 4 is an enlarged, fragmented portion of the crucible and susceptor assembly of FIG. 2; and

FIG. 5 is a top plan view of a susceptor of the susceptor assembly of FIG. 2.

Corresponding reference characters indicate corresponding parts throughout the several views of the drawings.

### DETAILED DESCRIPTION OF THE PREFERRED EMBODIMENT

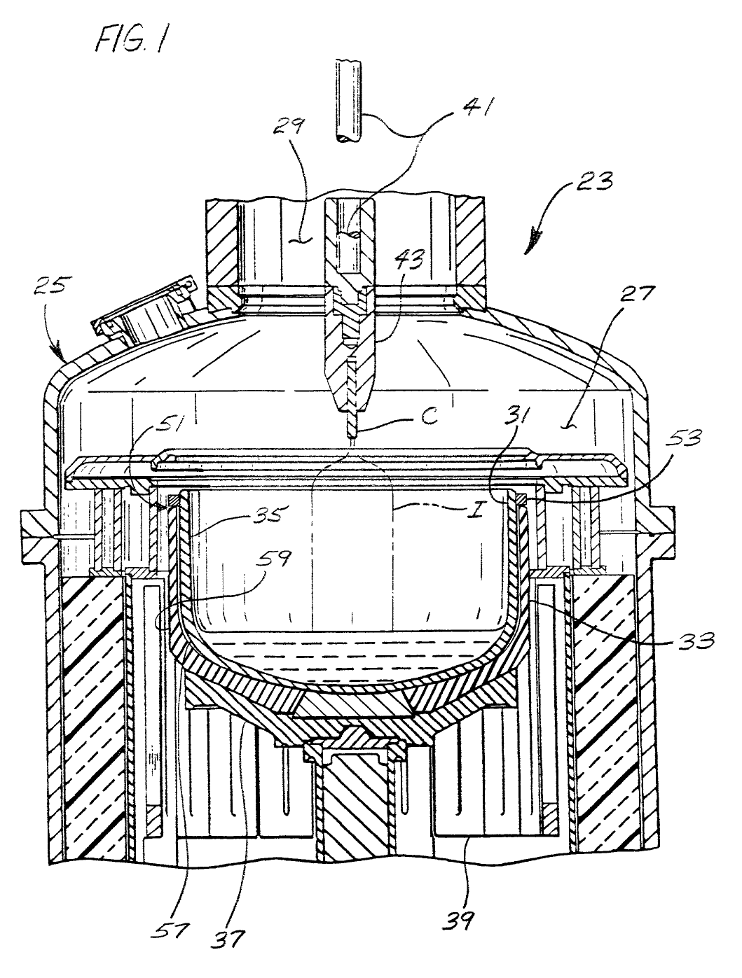

Referring now to the drawings and in particular to FIG. 1, a crystal puller of the present invention of the type used to grow monocrystalline silicon ingots (e.g., ingot I as shown in phantom in FIG. 1) according to the Czochralski method is generally indicated at 23. The crystal puller 23 includes a water cooled housing, generally indicated at 25, for isolating an interior which includes a lower crystal growth chamber 27 and an upper pull chamber 29 having a smaller transverse dimension than the growth chamber. A crucible 31 is seated in a susceptor 33 and has a cylindrical side wall 35. The crucible 31 contains molten semiconductor source material M from which the monocrystalline silicon ingot I is grown. The susceptor 33 is mounted on a turntable 37 for rotation of the susceptor and crucible 31 about a central longitudinal axis X of the crystal puller 23. The crucible 31 is also capable of being raised within the growth chamber 27 to maintain the surface of the molten source material M at a generally constant level as the ingot I is grown and source material is removed from the melt. A resistance heater 39 surrounds the susceptor 33 for heating the susceptor and the crucible 31 to melt the source material M in the crucible. The heater 39 is controlled by an external control system (not shown) so that the temperature of the molten source material M is precisely controlled throughout the pulling process.

A pulling mechanism includes a pull shaft 41 extending down from a mechanism (not shown) capable of raising, lowering and rotating the pull shaft. The crystal puller 23 may have a pull wire rather than a shaft 41, depending upon the type of puller. The pull shaft 41 terminates in a seed crystal chuck 43 which holds a seed crystal C used to grow the monocrystalline ingot I. The pull shaft 41 has been partially broken away in FIG. 1 for clarity in illustration of a raised position of the seed chuck 43 and ingot I. The general construction and operation of the crystal puller 23, except to the extent explained more fully below, is well known to those of ordinary skill in the art and will not be further described.

The crucible 31 of the illustrated embodiment is constructed of fused silica (i.e., quartz) and the susceptor 33 is constructed of graphite. At high temperatures such as those experienced in a crystal puller (e.g., about 1500° C.), graphite reacts with fused silica as follows:

SiO₂+C→SiO+CO [1]

SiO+2C→SiC+CO [2]

The first reaction [1] is a solid state reaction resulting in gaseous SiO and CO as a product. The gaseous SiO then reacts with the graphite in accordance with the second reaction [2] to form SiC. In other words, the SiC is formed by conversion of the graphite from which the susceptor is constructed.

### Experiment

An experiment comprising four test runs was conducted in a high temperature vacuum furnace to determine whether the conversion of graphite to SiC could be inhibited by manipulating the first reaction [1 ]. For each run, a block of fused silica and a block of graphite were weighed and then placed in abutting relationship with each other in the furnace. The blocks were heated at a predetermined temperature and pressure for a predetermined time period. In the first three runs, the blocks were generally flat to provide surface-to-surface contact with one another along substantially the entire surface of the graphite block. The temperature to which the blocks were heated was varied (e.g., 1000° C., 1250° C. and 1500° C.) for each of the three runs. In the fourth run, a fused silica block having a generally arched configuration was used to form a gap of about 3 mm between the fused silica block and the center of the graphite block when the blocks were placed in abutting relationship, and the blocks were heated to about 1500° C.

After each run, the blocks were allowed to cool and were again weighed to determine the weight loss or weight gain resulting from the reactions between the blocks. It is known that the weight of SiC is 1.66 times greater than carbon and, as a result, the graphite block would experience weight gain, or less weight loss, where the second reaction [2] occurs and the graphite of the susceptor is converted to SiC. The results of the experiment are indicated in the following table.

TABLE I
Pressure = 23 torr, Time = 24 hours

| | | | | Contact between |
|---|---|---|---|---|
| | | Weight loss of | Weight loss of | graphite and fused |
| Experiment | Temperature | Graphite(%) | Fused Silica(%) | silica |
| #1 | 1500° C. | 0.0136 | 0.9399 | No gap |
| #2 | 1250° C. | 0.0084 | 0.0193 | No gap |
| #3 | 1000° C. | 0.0055 | 0.0054 | No gap |
| #4 | 1500° C. | 0.0098 | 0.6054 | Gap of 3 mm |

As indicated by the results of the first three runs, the weight loss of the graphite and fused silica blocks increases as the temperature of the reaction increases. Observation of the graphite blocks after each of the first three runs indicated that no SiC was present. The weight loss of the graphite and fused silica is therefore due to the first reaction [1] between the graphite and the fused silica producing SiO and CO gas. The increased weight loss of the graphite block is also a result of the lack of SiC present (e.g., the lack of conversion of the graphite to SiC. Because the blocks were in contact relationship with each other, SiO gas produced as a result of the first reaction could not escape from between the blocks. As a result, the concentration of SiO and CO gas between the blocks increased to a concentration at which the forward reaction (e.g, the first reaction [1]) was retarded, thereby inhibiting the occurrence of the second reaction [2]. Consequently, once the first reaction [1] stopped, the graphite block no longer reacted with the SiO gas and hence the graphite was not converted to sic.

Comparing the first run, in which the blocks were heated in close contact with each other to 1500° C., with the fourth run, in which the blocks were shaped to define a small gap therebetween and were heated to 1500° C., the weight loss of the graphite block was substantially lower for the fourth run (e.g., where the blocks defined a gap therebetween of about 3 mm). The lower weight loss resulting from the fourth run as compared to the weight loss resulting from the first run is due to the conversion of graphite to SiC in accordance with reaction [2] between the graphite and the fused silica.

Based on the results of this experiment, it was determined that formation of SiC could be inhibited by manipulating (e.g., retarding) the first reaction [1] between graphite and fused silica. If the gaseous products of the first reaction [1], i.e., SiO and CO, are not allowed to disperse, the concentration of these products between the reactant surfaces increases. When the concentrations of these products sufficiently increases, the first reaction is retarded and, as a result, the second reaction [2] is inhibited whereby graphite is no longer converted to SiC.

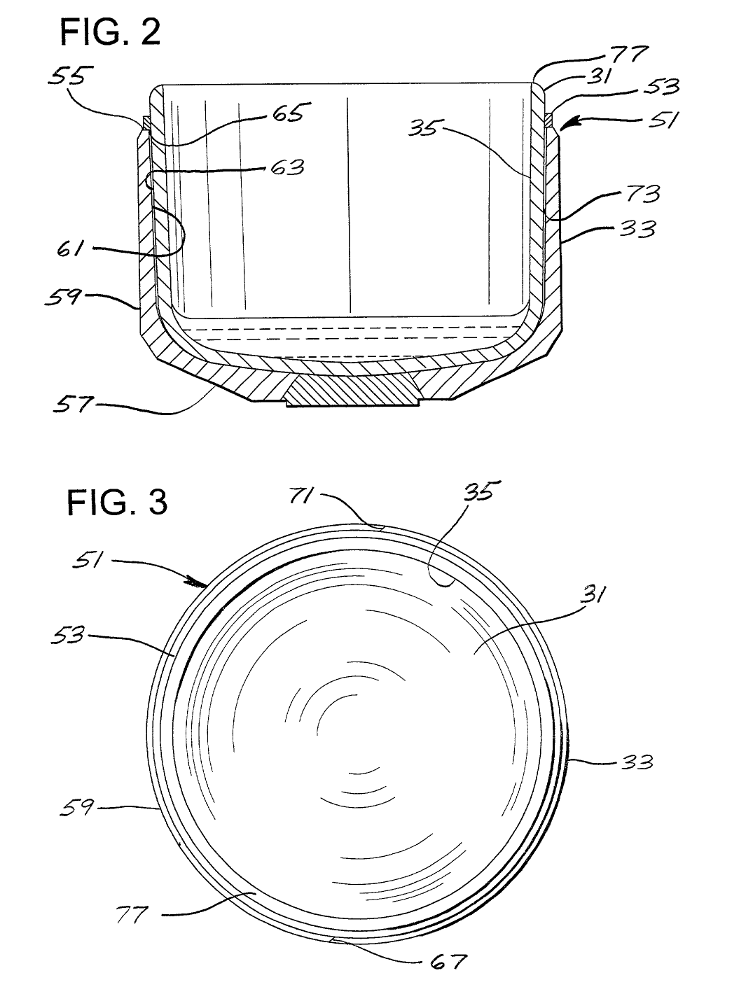

With reference to FIGS. 1 and 2, a susceptor assembly of the present invention is generally indicated at 51 and comprises the susceptor 33 for holding the crucible 31 in the crystal puller 23 and an annular sealing member 53 circumscribing the crucible and seating on an upper rim 55 of the susceptor. The susceptor 33 has a generally bowl-shaped bottom 57 and a cylindrical side wall 59 sized for receiving the crucible 31 therein with an inner surface 61 of the susceptor side wall 59 disposed in radially opposed relationship with an outer surface 63 of the crucible side wall 35. A central opening 60 in the bottom of the susceptor 33 receives part of the turntable 37 therein for properly seating the susceptor on the turntable. The crucible side wall 35 extends up within the crystal puller 23 to above the upper rim 55 of the susceptor 33 such that the uppermost radially opposed relationship between the crucible 31 and the susceptor is defined by the upper rim of the susceptor. An annular seam 65 is defined between the upper rim 55 of the susceptor 33 and the outer surface 63 of the crucible side wall 35 radially opposed to the upper rim of the susceptor. As an example, the crucible side wall 35 of the illustrated embodiment extends approximately one inch (25.4 mm) above the upper rim 55 of the susceptor 33. The thickness of the susceptor side wall 59 is approximately 19 mm.

The susceptor 33 is preferably of two-piece construction (FIG. 5) to allow for expansion and contraction of the quartz crucible 31 seated therein as the crucible is heated during operation of the crystal puller 23 and then subsequently cooled. The susceptor pieces generally abut one another other along a seam 67 comprising an arcuate, generally radially extending segment 69 in the bottom 57 of the susceptor 33 and a generally vertically extending segment 71 (the top of which is shown in FIG. 5 in the upper rim 55 of the susceptor). The vertically extending segment 71 of the seam 67 along which the susceptor pieces come together is directed generally non-radially through the susceptor side wall 35, such that the susceptor pieces radially overlap each other along the seam, for purposes which will become apparent. It is understood, however, that the vertically extending segment 71 of the seam 67 may be directed radially through the susceptor side wall 35 without departing from the scope of this invention. It is also understood that the susceptor 33 may be of unitary construction, or may be constructed of more than two pieces, and remain within the scope of this invention.

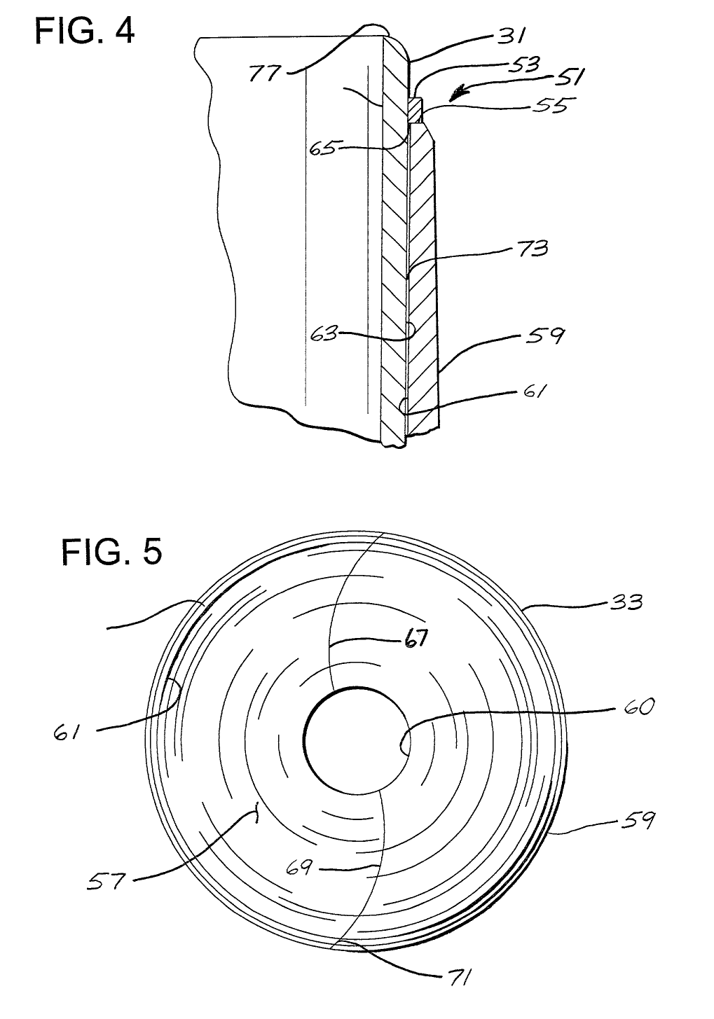

With particular reference to FIG. 4, due to manufacturing specifications and tolerances associated with the manufacture of quartz crucibles and graphite susceptors, the crucible 31 may not seat in the susceptor 31 with the crucible side wall 35 in close contact relationship with the susceptor side wall 59 along the entire inner surface 61 of the susceptor side wall. As a result, there may be an annular gap 73, such as up to about 5-6 mm, between the crucible outer surface 63 and the susceptor inner surface 61, including at the annular seam 65 between the upper rim 55 of the susceptor 33 and the outer surface of the crucible side wall 35. It is understood that the gap 73 may not be continuous, for example, the crucible 31 may be in close contact relationship with portions of the inner surface 61 of the susceptor side wall 59 and spaced from the remaining portions of the susceptor side wall, such that multiple gaps are present between the crucible side wall and the susceptor side wall, without departing from the scope of this invention.

The annular sealing member 53 is preferably a flexible strip constructed of graphite, and more preferably of isomolded graphite. It also contemplated that the sealing member 53 may alternatively be constructed of carbon, and more particularly of carbon fiber composite, without departing from the scope of this invention. The sealing member 53 is sized for seating on the upper rim 55 of the susceptor 33 in close contact relationship with the outer surface 63 of the crucible side wall 35 substantially about the entire outer circumference of the crucible side wall to cover the annular seam 65 defined by the upper rim of the susceptor and the outer surface of the crucible side wall. The sealing member 65 thus generally seals gaseous product, produced in the reaction between the graphite and the fused silica, between the crucible side wall and the susceptor side wall. As an example, the annular sealing member 65 of the illustrated embodiment is approximately one-half inch (12.7 mm) in height and has a thickness of approximately 10 mm.

The crystal puller 23 of the present invention is shown and described herein as having a crucible 31 and susceptor 33 wherein the crucible side wall 35 extends up within the crystal puller to above the upper rim 55 of the susceptor 33 such that the annular seam 65 over which the sealing member 53 is positioned is defined by the outer surface 63 of the crucible side wall and the upper rim of the susceptor. However, it is understood that the crucible 31 and susceptor 33 may be sized relative to each other in a manner other than that set forth above and shown in the drawings without departing from the scope of this invention, as long as the sealing member 53 engages both the susceptor and the crucible to cover the annular seam defined by the uppermost radially opposed relationship therebetween. For example, the crucible 31 may be sized such that an upper rim 77 of the crucible 31 is flush with the upper rim 55 of the susceptor 33. The sealing member 53 would thus seat on both the upper rim 77 of the crucible 31 and the upper rim 55 of the susceptor 33 over the annular seam defined between the radially opposed upper rims of the crucible and the susceptor. As another example, the susceptor side wall 59 may extend up within the crystal puller to above the upper rim 77 of the crucible 31. In such a configuration, the sealing member 53 would seat on the upper rim 77 of the crucible 31 in close contact relationship with the inner surface 61 of the susceptor side wall 59 over an annular seam 65 defined between the upper rim of the crucible and radially opposed inner surface of the susceptor side wall.

In operation according to a method of the present invention for growing monocrystalline ingots, polycrystalline silicon is deposited in the crucible 31, which is seated in the susceptor 33, and is melted by heat radiated from the crucible heater 39. The seed crystal C is brought into contact with the molten silicon source material S and a single crystal ingot I is grown by slow extraction via the pulling mechanism. The susceptor side wall 59 and crucible side wall 35 are heated by the heater 39 and by the molten source material S in the crucible 31. As the temperature of the susceptor 33 and crucible 31 increases, the graphite of the susceptor reacts with the fused silica of the crucible according to the reactions [1], [2] set forth above. The annular sealing member 53 generally seals CO gas produced by the first reaction [1] against escaping from between the crucible side wall 35 and the susceptor side wall 59. The concentration of CO gas between the crucible side wall 35 and the susceptor side wall 59 thereby increases and, as discussed above, the increased concentration inhibits further reaction of the fused silica and graphite according to the first reaction [1]. As a result, the formation of SiC (i.e., conversion of the graphite) according to the second reaction [2] is inhibited. The non-radially directed vertical segment 71 of the seam 67 along which the susceptor pieces come together inhibits the escape of CO gas through the susceptor side wall 59 by presenting an indirect path of escape for the Co.

In view of the above, it will be seen that the several objects of the invention are achieved and other advantageous results attained. Providing a crystal puller 23 with a susceptor assembly 51 having a sealing member 53 that engages the susceptor 33 and crucible 31 over a seam 65 defined therebetween substantially seals gas between the radially opposed surfaces of the susceptor and crucible. As a result gaseous CO is inhibited against escaping from between the crucible 31 and the susceptor 33, thus retarding the first chemical reaction [1] therebetween. The formation of SiC (i.e., conversion of the graphite) in accordance with the second reaction [2] is therefore inhibited. As a result, stresses introduced inside the susceptor 33 are decreased, thereby reducing the risk of distortion or cracking of the susceptor and thus increasing the useful life of the susceptor.

In view of manufacturing specifications and tolerances associated with the manufacture of quartz crucibles and graphite susceptors, the manner in which each crucible 31 seats within each susceptor 33 is different, such that the size of any gap 73, or gaps, present between the crucible and susceptor will vary. By placing the annular sealing member 53 over the annular seam 65 defined between the uppermost radially opposed relationship between the crucible 31 and the susceptor 33, instead of down between the crucible and the susceptor, one sealing member may be used regardless of the size of any gaps therebetween. As a result, the need for blanketing or otherwise covering or shielding the inner surface 61 of the susceptor 33 is eliminated. Thus, the annular sealing member 53 is less costly to manufacture than a sheet intended to cover the entire inner surface 61 of the susceptor 33.

When introducing elements of the present invention or the preferred embodiment(s) thereof, the articles “a”, “an”, “the” and “said” are intended to mean that there are one or more of the elements. The terms “comprising”, “including” and “having” are intended to be inclusive and mean that there may be additional elements other than the listed elements.

As various changes could be made in the above constructions without departing from the scope of the invention, it is intended that all matter contained in the above description or shown in the accompanying drawings shall be interpreted as illustrative and not in a limiting sense.

What is claimed is:

1. A crystal puller for producing a monocrystalline ingot, the crystal puller comprising:
a susceptor having a bottom and a side wall;
a crucible for holding molten source material, said crucible being received in the susceptor and having a side wall disposed in generally radially opposed relationship with the susceptor side wall;
a heater in thermal communication with the susceptor and crucible for heating the crucible to a temperature sufficient to melt the source material held by the crucible;
a pulling mechanism positioned above the crucible for pulling the ingot from the molten source material held by the crucible; and
a sealing member adapted for close contact relationship with the crucible side wall and the susceptor side wall to generally seal between the crucible and the susceptor any gaseous product resulting from a reaction of the crucible with the susceptor against escape from between the crucible and the susceptor thereby retarding the reaction of the crucible with the susceptor.

2. A crystal puller as set forth in claim 1 wherein the uppermost radially opposed relationship between the crucible side wall and the susceptor side wall defines a seam therebetween, the sealing member being in close contact relationship with the susceptor side wall and the crucible side wall generally over said seam to generally seal any gaseous product resulting from a reaction of the crucible with the susceptor against escape from between the crucible and the susceptor.

3. A crystal puller as set forth in claim 2 wherein the seam is defined by the crucible side wall and an upper rim of the susceptor side wall, the sealing member seating on the upper rim of the susceptor side wall in close contact relationship with the crucible side wall substantially about the entire circumference of the crucible side wall generally over said seam.

4. A crystal puller as set forth in claim 3 wherein the crucible side wall extends up within the crystal puller to above the upper rim of the susceptor side wall such that the seam is defined by the upper rim of the susceptor side wall and an outer surface of the crucible side wall, the sealing member seating on the upper rim of the susceptor in close contact relationship with the outer surface of the crucible side wall substantially about the entire circumference of the outer surface of the crucible side wall generally over said seam.

5. A crystal puller as set forth in claim 1 wherein the sealing member is constructed of graphite.

6. A crystal puller as set forth in claim 5 wherein the sealing member is constructed of isomolded graphite.

7. A crystal puller as set forth in claim 1 wherein the susceptor is constructed of at least two pieces, the susceptor pieces generally abutting one another other along a seam comprising a generally vertically extending segment within in the side wall of the susceptor.

8. A crystal puller as set forth in claim 7 wherein the vertically extending segment of the seam between abutting susceptor pieces is directed generally non-radially through the side wall of the susceptor such that the susceptor pieces radially overlap each other along the seam to further inhibit gaseous product against escaping from between the susceptor and the crucible.

9. A susceptor assembly for use in a crystal puller of the type used for growing a monocrystalline ingot from molten source material contained in a crucible in the crystal puller, the susceptor assembly comprising:
a susceptor having a bottom and a side wall, the susceptor being sized for receiving and holding the crucible in the crystal puller, the side wall of the susceptor being in generally radially opposed relationship with a side wall of the; and
a sealing member adapted for close contact relationship with the crucible side wall and the susceptor side wall to generally seal between the crucible and the susceptor any gaseous product resulting from a reaction of the crucible with the susceptor against escape from between the crucible and the susceptor thereby retarding the reaction of the crucible with the susceptor.

10. A crystal puller as set forth in claim 9 wherein the uppermost radially opposed relationship between the crucible side wall and the susceptor side wall defines a seam therebetween, the sealing member being adapted for close contact relationship with the susceptor side wall and the crucible side wall over said seam to generally seal between the crucible and the susceptor any gaseous product resulting from a reaction of the crucible with the susceptor against escape from between the crucible and the susceptor.

11. A crystal puller as set forth in claim 10 wherein the susceptor side wall has an upper rim, the seam being defined by the crucible side wall and the upper rim of the susceptor side wall, the sealing member being adapted for seating on the upper rim of the susceptor side wall in close contact relationship with the crucible side wall substantially about the entire circumference of the crucible side wall to seat over said seam.

12. A crystal puller as set forth in claim 11 wherein the susceptor is sized such that the crucible side wall extends up within the crystal puller to above the upper rim of the susceptor side wall whereby the seam is defined by the upper rim of the susceptor side wall and an outer surface of the crucible side wall, the annular sealing member being adapted for seating on the upper rim of the susceptor in close contact relationship with the outer surface of the crucible side wall substantially about the entire circumference of the outer surface of the crucible side wall to seat over said seam.

13. A crystal puller as set forth in claim 9 wherein the annular sealing member is constructed of graphite.

14. A crystal puller as set forth in claim 13 wherein the annular sealing member is constructed of isomolded graphite.

15. A crystal puller as set forth in claim 9 wherein the susceptor is constructed of at least two pieces, the susceptor pieces generally abutting one another other along a seam comprising a generally vertically extending segment within in the side wall of the susceptor.

16. A crystal puller as set forth in claim 15 wherein the vertically extending segment of the seam between abutting susceptor pieces is directed generally non-radially through the side wall of the susceptor such that the susceptor pieces radially overlap each other along the seam to further inhibit gaseous product against escaping from between the susceptor and the crucible.

17. A method for growing monocrystalline ingots from molten source material in a crystal puller of the type having a crucible adapted for holding source material and a heater adapted for heating the crucible to melt the source material in the crucible, the method comprising the steps of:
seating the crucible in a susceptor mounted in the crystal puller, the susceptor having a bottom and a side wall in generally radially opposed relationship with a side wall of the crucible;
charging semiconductor source material to the crucible;
heating the susceptor and crucible to a temperature sufficient to melt the semiconductor source material held by the crucible, said heating causing the crucible to react with the susceptor therebetween to produce a gaseous product; and
generally sealing said gaseous product between the susceptor and crucible to increase the concentration of said gaseous product therebetween, thereby inhibiting further reaction of the crucible with the susceptor.

18. The method set forth in claim 17 wherein the uppermost radially opposed relationship between the crucible and the susceptor defines a seam therebetween, the step of generally sealing said gaseous product between the susceptor and the crucible comprising placing a sealing member over said seam in close contact relationship with the susceptor side wall and the crucible side wall.

19. The method set forth in claim 18 wherein the susceptor side wall has an upper rim, the seam being defined by the crucible side wall and the upper rim of the susceptor side wall, the step of placing a sealing member over the seam comprising seating the sealing member on the upper rim of the susceptor side wall in close contact relationship with the crucible side wall substantially about the entire circumference of the crucible side wall.
